(19) United States
(12) Patent Application Publication
(10) Pub. No.: US 2008/0061339 A1
(43) Pub. Date: Mar. 13, 2008

(54) SEMICONDUCTOR DEVICE HAVING CAPACITANCE ELEMENT, ARRANGED CLOSE TO MOS TRANSISTOR AND HAVING DIELECTRIC MADE OF ELECTROSTRICTIVE MATERIAL

(75) Inventors: Kensuke OKONOGI, Tokyo (JP); Kiyonori OHYU, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/852,045

(22) Filed: Sep. 7, 2007

(30) Foreign Application Priority Data
Sep. 11, 2006 (JP) 2006-246120

(51) Int. Cl. H01L 27/108

(52) U.S. Cl. 257/296; 257/E27.085

(57) ABSTRACT

A semiconductor device includes a single-crystal semiconductor substrate; and a stress applying device for applying a desired mess to specific one or more parts on or in the single-crystal semiconductor substrate. Typically, the stress applying device includes a capacitance element, which is arranged in the vicinity of the specific one or more parts, and has a dielectric made of an electrostrictive material; and a device for applying a voltage in a direction parallel to a polarization vector of the dielectric. The specific one or more parts may be one or more p-n junctions, each of which may be included in a MOS transistor. In this case, each MOS transistor may function as a redundant cell or a main cell for forming a DRAM. The desired stress may be applied in a predetermined direction, and may have an amount for applying a desired distortion to the specific one or more parts.

### BACKGROUND OF THE INVENTION

1. Field of the Invention

The present invention relates to a semiconductor device such as a memory device represented by a DRAM, a logic device, or the like, and in particular, relates to a semiconductor device for suppressing influence of distortion, which has occurred in a transistor as a constituent of the semiconductor device, and for maintaining stable transistor characteristics for a long period of time.

Priority is claimed on Japanese Patent Application No. 2006-246120, filed Sep. 11, 2006, the content of which is incorporated herein by reference.

2. Description of the Related Art

Recently, IC memory devices such as a DRAM (dynamic random access memory) have employed a method in which an auxiliary cell (or a redundant cell) is formed in advance on a chip, in addition to memory cells (i.e., main cells) corresponding to the original storage capacity. When a defect cell is included in the main cells, the redundant cell is substituted for the defect cell, so that the IC memory device still functions as a non-defective chip having the original storage capacity.

However, if the substitute new (i.e., redundant) cell is a defect cell, the IC memory device cannot function as a non-defective chip. In recent years, a substandard state such as a variation in the refresh time (i.e., VRT (variable retention time) as shown in FIG. 1) may be found through a refresh time test. Such a variation is observed in quite a few cells among a large number of memory cells, and in the variation, one of two refresh times (i.e., retention times) is measured at each measurement point. That is, when the measurement of the refresh time is performed for a long period of time, the measured value shifts between two refresh times. This phenomenon is called “VRT”. When VRT occurs in a redundant cell, even when the redundant cell is substituted for a defect cell, the IC memory cell device cannot function as a non-defective chip having the original storage device, and thus forming the redundant cell has no meaning.

The inventors of the present invention reported that a vacancy defect called “vacancy-oxygen complex defect” (refer to FIG. 2) participates in the above VRT (see Non-Patent Document 1).

On the other hand, at preset logic devices actively employ a method in which a material having a membrane stress is used in a pre-process so as to intentionally add a distortion and to improve transistor characteristics (i.e., on-current characteristics). However, it is known that distortion in a transistor occurs, not only by stress generated in any material during the fabrication (i.e., the pre-process) of the transistor, but also by, for example, a resin material formed (for sealing) in a packaging process (i.e., a post-process). That is, even when an appropriate distortion is provided in a transistor during the pre-process, the distortion varies due to an influence of a post-process, so that desired transistor characteristics cannot be obtained.

As described above, with respect to conventional semiconductor devices, even when device characteristics vary due to a distortion which occurs in a transistor (as a constituent of the relevant device) after an IC memory device (e.g., a DRAM) or a logic device is formed, there a no means for flexibly coping with this problem (i.e., variation).
Non-Patent Document 1: T. Umeda, et al., “Single silicon vacancy-oxygen complex defect and variable retention time phenomenon in dynamic random access memories”, Applied Physics Letters 88, pp. 253504-1 to 253504-3, 2006.

### SUMMARY OF THE INVENTION

In light of the above circumstances, an object of the present invention is to provide a semiconductor device such as an IC device (represented by a DRAM) or a logic device, which can maintain stable transistor characteristics even when a distortion, which has occurred in a transistor as a constituent of the device, varies after forming the device.

Therefore, the present invention provides a semiconductor device comprising:

a single-crystal semiconductor substrate; and

a stress applying device for applying a desired stress to specific one or more parts on or in the single-crystal semiconductor substrate.

In accordance with this structure, a desired stress can be applied to specific one or more parts on or in a single-crystal semiconductor substrate (e.g. a silicon substrate). Therefore, it is possible to provide a semiconductor device, by which even when distortion, which has occurred in a specific part such as a transistor, varies after the semiconductor device is formed, stable (transistor) characteristics can be maintained.

In a typical example, the stress applying device includes:

a capacitance element, which is arranged in the vicinity of the specific one or more parts, and has a dielectric made of an electrostrictive material; and

a voltage applying device for applying a voltage in a direction parallel to a polarization vector of the dielectric.

Therefore, a desired (compressive or tensile) stress can be applied to the specific one or more part in the vicinity of the capacitance element, by controlling the amount of distortion of the electrostrictive material. In order to control the amount of distortion of the electrostrictive material, the voltage applying device for applying a voltage in a direction parallel to the polarization vector of the dielectric is used.

In a preferable example, the capacitance element is arranged on a side of the specific one or more parts, and the direction of the polarization vector of the dielectric is parallel to the <110> or <100> direction with respect to the x-y-z coordinate system.

In another preferable example, the capacitance element is arranged under the specific one or more parts, and the direction of the polarization vector of the dielectric is parallel to the <110> or <100> direction with respect to the x-y-z coordinate system.

Typically, the specific one or more parts are one or more p-n junctions.

In this case, the one or more p-n junctions nay be each included in a MOS transistor. Each MOS transistor may function as a redundant cell or a main cell for forming a DRAM.

Typically, the desired stress is one of a compressive stress and a tensile stress.

Also typically, the desired stress is applied in a predetermined direction.

Preferably, the desired stress has an amount for applying a desired distortion to the specific one or more parts.

### BRIEF DESCRIPTION OF THE DRAWINGS

FIG. 1 is a graph showing an example of a refresh-time variation phenomenon (VRT).

FIG. 2 is a schematic diagram showing a mechanism (or model) of the refresh-time variation.

FIG. 3 is a schematic sectional view showing a transistor structure of a DRAM as a representative example of the semiconductor device.

FIG. 4 is a schematic plan view showing a transistor array part after the gate electrodes are formed in the transistor structure shown in FIG. 3.

FIG. 5 is a schematic sectional view along line B-B in FIG. 4.

FIG. 6 is a schematic sectional view showing an example of measurement results of electric field intensity in a DRAM transistor structure.

FIG. 7 is a schematic sectional view showing an example of measurement results of distortion in a DRAM transistor structure.

FIG. 8 is a schematic diagram showing a mechanism (or model) of the refresh-time variation.

FIGS. 9A and 9B are sectional views showing an example of the semiconductor device with respect to the present invention.

FIG. 10 is a plan view showing an example in which the method shown by FIGS. 9A and 9B is applied to redundant cells in a DRAM.

FIGS. 11A and 11B are sectional views showing another example of the semiconductor device with respect to the present invention.

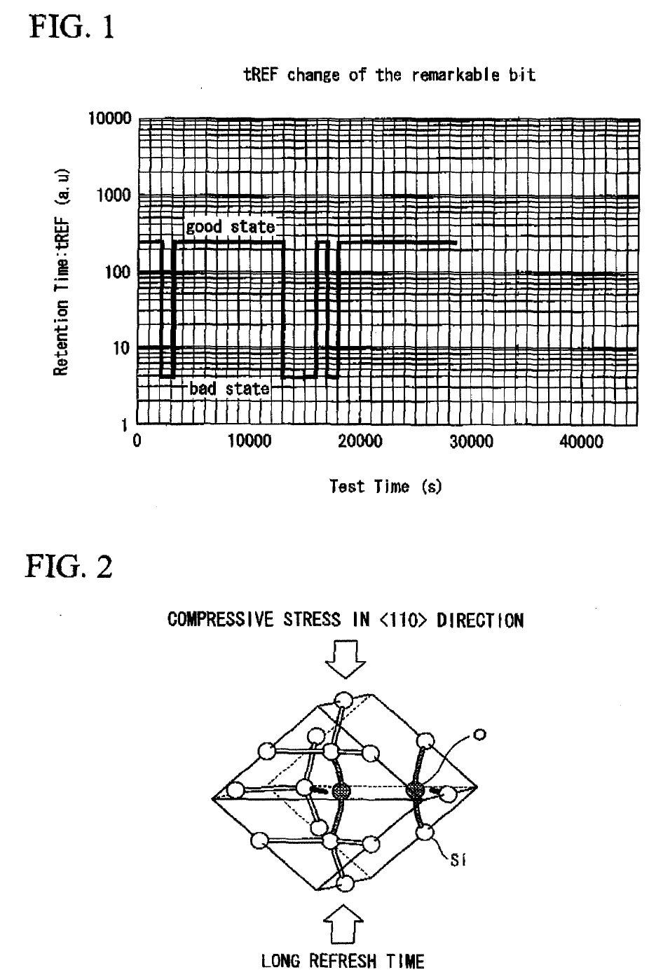

### DETAILED DESCRIPTION OF THE INVENTION

The present invention has been provided based on the results of investigation and development with respect to DRAMs, as explained below in detail.

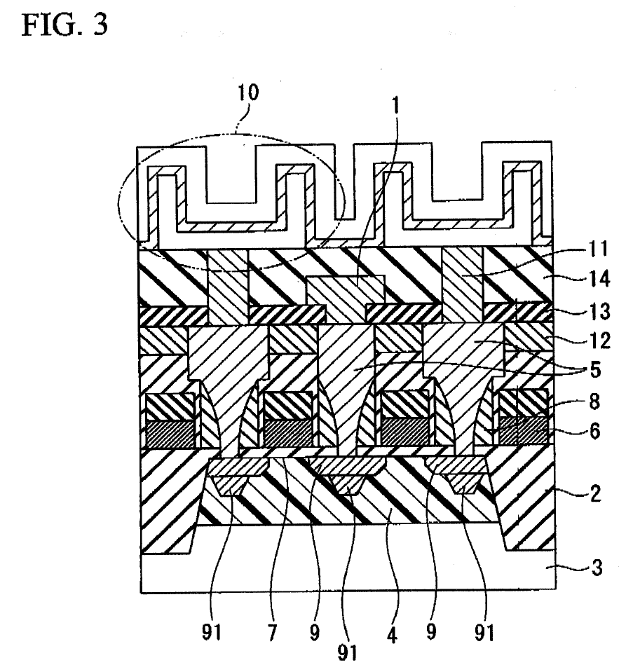

FIG. 3 is a schematic sectional view showing a transistor structure of a DRAM as a representative example of the semiconductor device. As shown in FIG. 3, in the transistor structure of the DRAM, two transistors, which commonly use one bit line 1, are formed in one active area. An example of the structure almost similar to FIG. 3 is disclosed, for example, in FIG. 19 of Japanese Unexamined Patent Application, First Publication No. 2003-17586.

The transistor structure of FIG. 3 has an active area surrounded by a trench-form element-isolation area (i.e., STI (shallow trench isolation)) in which an insulating film 2 is buried. In the active area, at least a p-type well layer 3, to which a substrate potential is applied, and a p-type channel dope layer 4 for determining a threshold voltage of a relevant transistor are formed. Under the p-type well layer 3, an n-type buried well layer (not shown) is present. In addition, two gate electrodes 6 are formed on both sides of a plug 5, which is connected to a bit line 1 and is made of polysilicon. A gate insulating film 7 is formed between the gate electrodes 6 and the p-type channel dope layer 4.

Between each gate electrode 6 and the adjacent plug 5, a side spacer 8 is formed. In each part (of the active area) where no gate electrode 6 is formed, an n-type low-concentration diffusion layer 9 is formed, which functions as a source or drain. Each n-type low-concentration diffusion layer 9 is connected to a plug 5 connected to the bit line 1, or a plug 5 connected to a plug 11, which is further connected to a capacitor 10. Each polysilicon plug 5 is provided by forming a hole in the inter-layer insulating film 12, and then drawing and depositing polysilicon, to which phosphorus of approximately 2×10²⁰/cm³ has been injected. Here, immediately after forming the hole, a phosphorus injection part 91 may be formed so as to decrease the electric field. Generally, such a phosphorus injection part 91 for decreasing the electric field is formed deeper than the n-type low-concentration diffusion layer 9. In addition, an inter-layer insulating film 13 is provided between the plug 11 and the bit line 1, and an inter-layer insulating film 14 is provided between the bit line 1 and the capacitor 10.

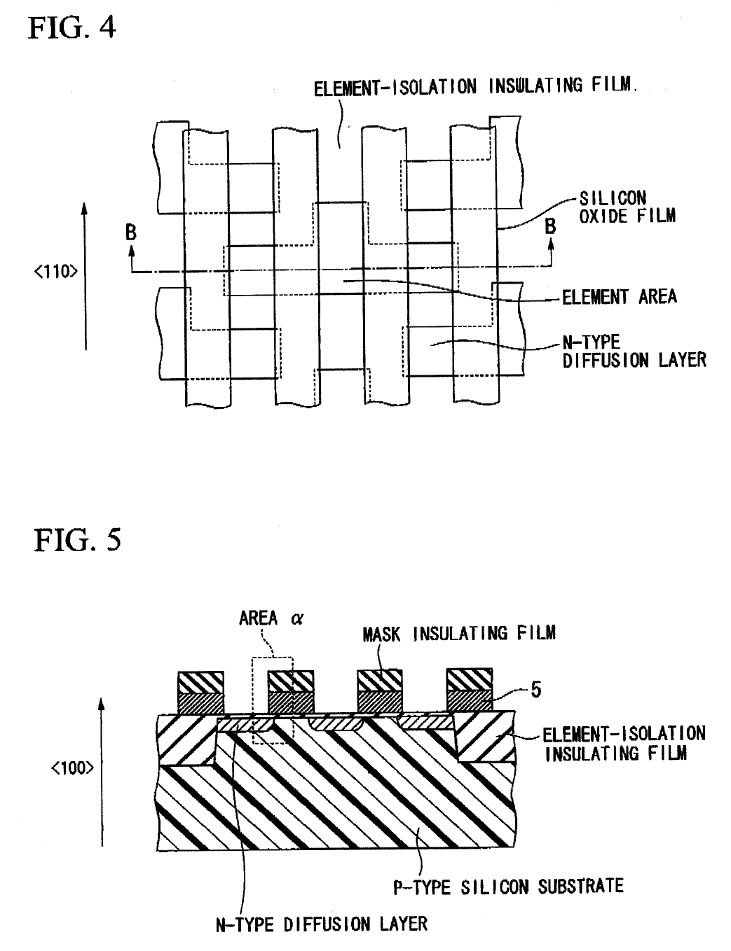

FIG. 4 is a schematic plan view showing a transistor array part after the gate electrodes are formed in the transistor structure shown in FIG. 3. FIG. 5 is a schematic sectional view along line B-B in FIG. 4.

In the transistor structure a shown in FIGS. 3 to 5, the procedure from contact hole formation to plug formation, which relates to the present invention, is generally performed as explained below. However, the procedure up to formation of source/drain diffusion areas for providing MOS (metal-oxide semiconductor) transistors and the procedure after the bit line 1 is formed, do not directly relate to the present invention, and explanation thereof are omitted here.

After each transistor MOS is formed, a silicon oxide film is deposited by a CVD (chemical vapor deposition) method. Then, polishing by CUP (chemical-mechanical polishing) is performed, and patterning of a resist is performed by lithography, so as to form contact holes. The oxide film is etched by dry etching using the above resist as a mask, thereby exposing the diffusion layer 9 as a base layer. After that, in order to decrease the electric field, phosphorus is injected at a density of 1.5×10¹³/cm³ and at a voltage of 60 kV, so that phosphorus injection parts 91 are formed.

Next, polysilicon, to which phosphorus is doped, is deposited by CVD on the silicon oxide film, wherein the inside of each contact hole is also subjected to the deposition. The polysilicon is then etched back (or polished by CMP), so that it remains only in the inside of each contact hole, thereby forming the polysilicon plugs 5.

Although it is not shown in Patent Document 1, thermal processing at approximately 950 to 1050° C. for 60 seconds is performed so as to activate phosphorus in the polysilicon plugs 5. After that, among two adjacent plugs 5, one is connected via the corresponding plug 11 to a base electrode in the relevant capacitor 10, and the other is connected to the bit line 1.

The inventors of the present invention have discovered that when the above transistor structure is fabricated, a number of vacancy-type defects (vacancy defects) are formed in the vicinity of a p-n junction during the thermal processing for activation (e.g., 950 to 1050° C. for 60 seconds), performed after a polycrystalline poly-plug layer as described above is formed. FIG. 2 shows a representative of the vacancy defects. Such vacancy defects occur because interstitial silicon in the source/drain diffusion layer (as the base layer) is absorbed due to the above-described change in the crystal structure of the polysilicon during the thermal processing, and such absorption increases the concentration of vacancies.

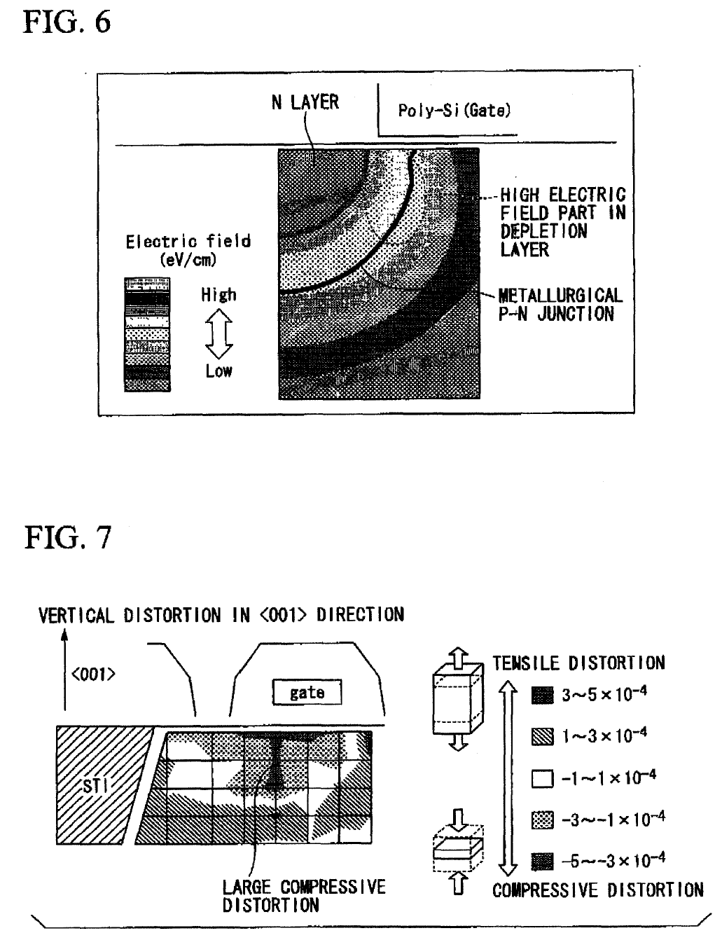

FIGS. 6 and 7 respectively show examples of measurement results of electric field intensity and distortion in a DRAM transistor structure. In the measurements, the area α in FIG. 5 is observed and measured. In accordance with FIGS. 6 and 7, it is found that a part having a relatively high electric field is present in an area under the gate electrode, and on a side of the n-type low-concentration diffusion layer 9 (for providing a source and a drain, that is, a p-n junction) and that a part having a relatively large compressive distortion is present in a substantially identical area. Therefore, with respect to the DRAM transistor structure as shown in FIGS. 3 to 5, the inventors have found that vacancy defects, which are present at a position having a high electric field in a p-n junction area on a cylinder-side in the relevant cell, produce a variation in the junction leakage current, which causes the above-described VRT phenomenon.

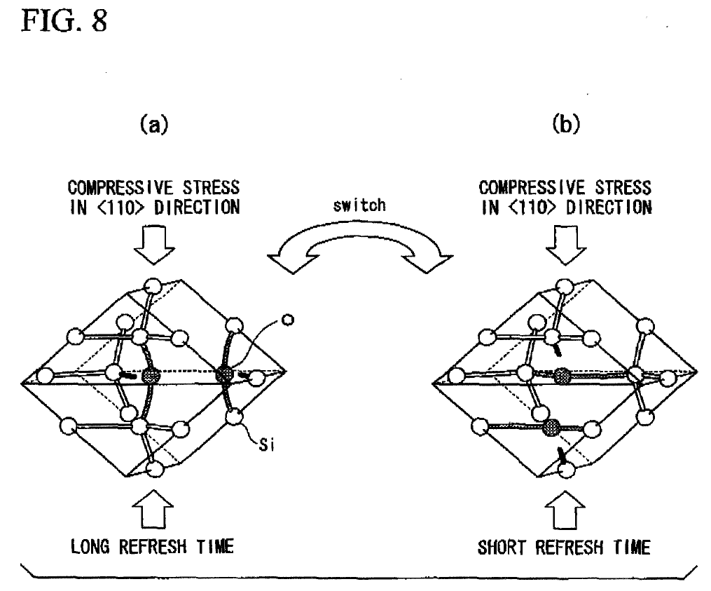

The inventors also found by using EDMR (electrically detected magnetic resonance) that the VRT phenomenon occurs by a reversible variation of the vacant defects, which receive compressive stress, between two transitionable states (see FIGS. 2 and 8). That is, vacancy defects have two stable orientation forms due to a compressive stress in the <110> direction with respect to the x-y-z coordinate system Here, in the case shown in the part (a) of FIG. 8, the leakage current is small (corresponding to a long refresh time) because the carrier trap level is distant from the middle gap (i.e., close to a conductive bandy while in the case shown in the part (b) in FIG. 8, leakage current is large (corresponding to a short refresh time) because the carrier trap level is close to the middle gap (i.e., distant from the conductive band and close to a valence band). Therefore, in the case of the part (b) in FIG. 8, a non-defective device is obtained through a refresh test; however, at a certain time, the state may transit to that shown in the part (b) of FIG. 8, which produces a defective device.

That is, the inventors have determined that if a cell which indicates a VRT phenomenon (called a “VRT cell” below) is present as a redundant cell, then even when the redundant cell is substituted for a defective cell, the cell will become defective in the future.

On basis of the above knowledge, the inventors have provided a semiconductor device having a plurality of MOS transistors, a capacitance element, which is arranged in the vicinity of specific one or more of the MOS transistors, and has a dielectric made of an electrostrictive material; and a device for applying a voltage in a direction parallel to a polarization vector of the dielectric.

In accordance with the semiconductor device having the above structure the dielectric for forming the capacitance element is made of an electrostrictive material. Thus, it is possible to apply a desired (compressive or tensile) stress to a specific MOS transistor in the vicinity of the capacitance element by controlling the amount of distortion of the electrostrictive material. The device for applying a voltage in a direction parallel to a polarization vector of the dielectric is preferably used for controlling the amount of distortion of the electrostrictive material. Accordingly, it is possible to provide a semiconductor device, by which even when distortion, which has occurred in a specific transistor, varies after the semiconductor device is formed, stable transistor characteristics can be maintained.

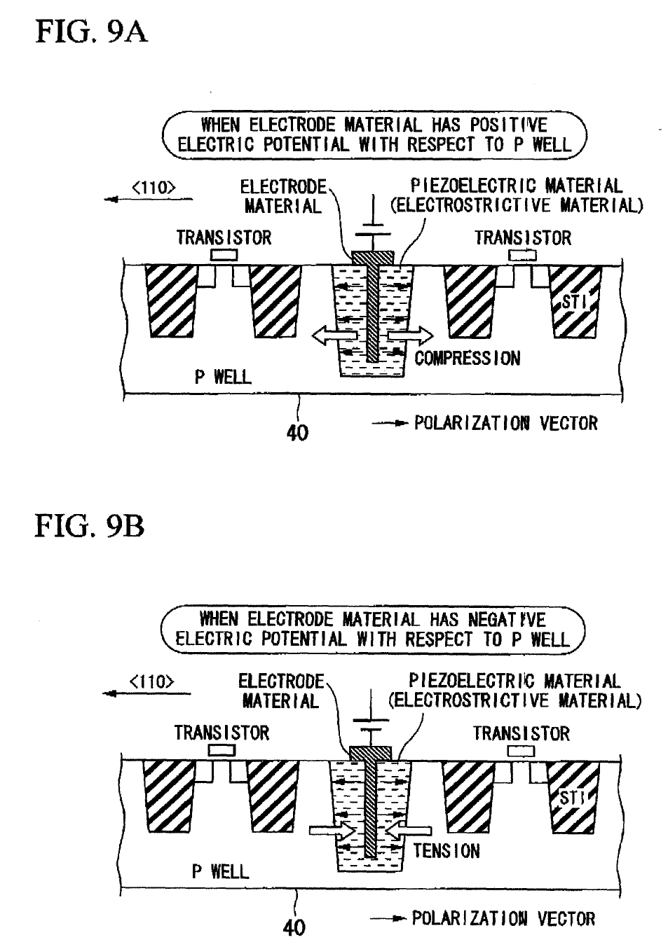

FIGS. 9A and 9B are schematic sectional views showing an example of the semiconductor device (e.g., an IC memory device represented by a DRAM). In this example, a capacitance element is arranged on a side of a specific MOS transistor, and the direction of the polarization vector of a dielectric, which forms the capacitance element, is parallel to the <110> or <100> direction with respect to the x-y-z coordinate system.

That is, in the semiconductor device shown in FIGS. 9A and 9B, a capacitance element having a capacitor structure, which is buried in a silicon substrate 40 (i.e., a single-crystal semiconductor substrate), is formed in the vicinity of a specific MOS transistor functioning as a redundant cell. An electrostrictive material (i.e., a piezoelectric material) is used as a dielectric material for the capacitance element, and one electrode is formed as a P well, and another electrode is buried in the dielectric material as shown in FIGS. 9A and 9B. Here, as shown in FIGS. 9A and 9B, the dielectric material is arranged along the depth direction of the silicon substrate 40, for example, in a space having a substantially rectangular sectional form. Accordingly, the direction of the polarization vector of the dielectric material is induced involuntarily to that substantially perpendicular to the depth direction of the silicon substrate 40.

Therefore, as shown in FIG. 9A, when a positive DC (direct current) voltage is applied in the same direction as the polarization vector of the dielectric material, the dielectric material extends in a direction substantially perpendicular to the depth direction of the silicon substrate 40, thereby providing a form for applying a compressive stress to a redundant cell. In contrast, as shown in FIG. 9B, when a negative DC voltage is applied, the dielectric material contracts in the direction substantially perpendicular to the depth direction of the silicon substrate 40, thereby providing a form for applying a tensile stress to a redundant cell.

Therefore, it is possible to apply a desired amount of distortion to a redundant cell in the vicinity of a capacitor structure by controlling the voltage applied between the electrode material and the P well.

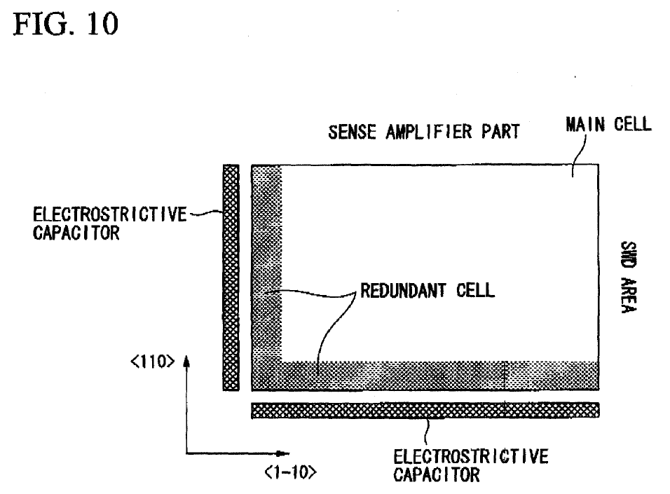

When actually applying this technique to a DRAM, an arrangement of the capacitor structure as shown in FIG. 10 may be employed. As shown in FIG. 10, a number of redundant cells are arranged in the outer periphery of an area (indicated by “MAIN CELL”) where a number of main cells are provided. A capacitor structure (indicated by “ELECTROSTRICTIVE CAPACITOR” in FIG. 10) may be arranged along the redundant cells, where a specific gap is provided between the redundant cells and the capacitor structure.

FIG. 10 shows an example in which a single capacitor structure is provided for a plurality of redundant cells arranged along each of two sides in the outer periphery of the main cell area. In this arrangement, it is important that the longitudinal direction of the capacitor structure is set to substantially the <110> or <1-10> direction. In accordance with such a structure, vacancy defects produce the VRT phenomenon, as explained using FIG. 8. Therefore, it is preferable and especially effective to arrange the capacitor at an area where the stress applied to the redundant cell in the <110> direction can be controlled.

Accordingly, when dependency of the refresh time on the voltage is estimated and the voltage applied between the electrode material and the P well is set to the most appropriate value, it is possible to substitute a redundant cell, which always has a long refresh time, for a defective cell.

FIG. 10 shows an example in which a single capacitor structure is provided for a plurality of redundant cells arranged along a side in the outer periphery of the main cell area. However, the capacitor structure is not limited to such a single structure, but a plurality of capacitor structures may be provided instead. At maximum, a capacitor structure may be provided for each redundant cell. When providing a plurality of the capacitor structure various characteristics of the capacitor structure (e.g., the kind or capacitance) and the arrangement of the capacitor structure with respect to the redundant cell(s) (e.g., the distance between them) can be adjusted for each corresponding part of the redundant cells.

That is, FIG. 10 shows a capacitor structure arrangement for handling the redundant cells. However, instead of the redundant cells, a capacitor structure may be provided for each, some, or all of the main cells, so as to provide similar functions and effects. There, the present invention contributes to the reduction of a variation in MOS-transistor characteristics of a memory device represented by a DRAM.

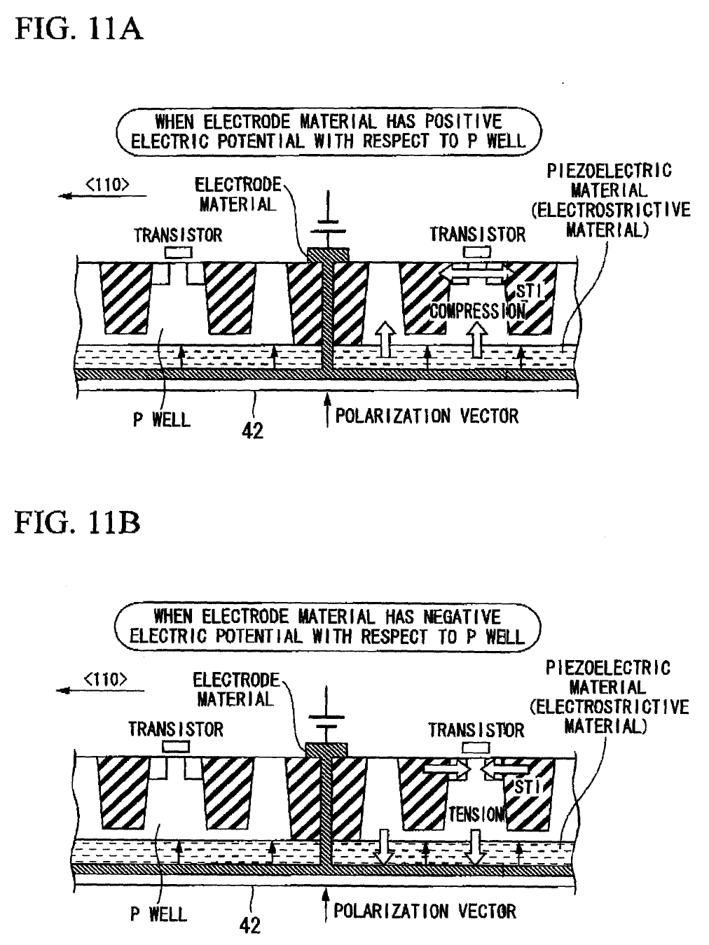

FIGS. 11A and 11B are schematic sectional views showing another example of the semiconductor device (here, a logic device) in accordance with the present invention.

A variation in the MOS-transistor characteristics, which is caused by stress application in a post-process, can be reduced using a capacitor structure arrangement as shown in FIGS. 11A and 11B. With respect to the structure shown in FIGS. 11A and 11B, a buried-capacitor structure may be formed in advance in the surface of a silicon substrate 42 (i.e., a single-crystal semiconductor substrate) where a transistor is formed, or a capacitor structure may be formed by separately fabricating an upper part positioned above an electrostrictive material (i.e., a piezoelectric material) and a lower part (which includes the electrostrictive material) positioned under the upper part, and adhering both parts together.

As shown in FIGS. 11A and 11B, an electrostrictive material (i.e., a piezoelectric material) is used as the dielectric material of a capacitor structure. In order to apply a tensile distortion (see the bidirectional void arrow) to a relevant transistor in the <110> direction, a positive DC voltage is applied with respect to the electric potential of the P well (see FIG. 11A). Accordingly, the electrostrictive material extends, so that the channel area of the relevant transistor is contracted in the <100> direction (see the upward void arrows), thereby applying a tensile distortion corresponding to the Poisson ratio in the <110> channel direction.

In contrast, in order to apply a compressive distortion to a relevant transistor in the <110> direction, a negative DC voltage is applied so as to contract the electrostrictive material (see FIG. 11B). Accordingly, it is possible to apply a compressive distortion corresponding to the Poisson ratio in the <110> channel direction.

The amount of distortion due to the voltage application can be controlled by the applied voltage. For example, when quartz (or rock crystal) is used as a dielectric of the capacitor (structure), it has a piezoelectric constant of “pm/V” order; therefore an applied voltage of approximately 1 V produces a distortion of a few ppm. PZT-4 (lead zirconate titanate), ZnO, LiNbOP₃, or the like, are also electrostrictive materials having a large piezoelectric constant. When using such an electrostrictive material having a large piezoelectric constant, a relatively large distortion can be produced by applying a relatively small voltage.

FIGS. 11A and 11B show an example in which a single capacitor structure is provided for a plurality of transistors. However, this is not a limiting condition, and a plurality of capacitor structures may be formed, and at maximum, a capacitor structure may be provided for each transistor. When providing a plurality of the capacitor structures, various characteristics of the capacitor structure (e.g., the kind or capacitance) and the arrangement of the capacitor struggle with respect to the relevant transistor (e.g., the distance between them, or whether the position of the structure overlaps the relevant transistor) can be adjusted for each corresponding part of the transistors.

In addition, FIGS. 11A and 11B show an example in which a capacitor structure is arranged with respect to a plurality of transistors, which are aligned to form at least a row (in the left-to-right direction on the plane of FIGS. 11A and 11B). However, the capacitor structure may be arranged with respect to a plurality of transistors, which are aligned to form a plurality of rows (provided in the depth direction with respect to the plane of FIGS. 11A and 11B). In addition, a capacitor structure may be individually provided for a specific transistor which is present in a specific row or at a specific position. The capacitor structure in accordance with the present invention can produce similar functions and effects for any transistor in any arrangement. Therefore, the present invention is also effective for suppressing a variation in the characteristics of MOS transistors in a logic device.

While preferred embodiments of the invention have been described and illustrated above, it should be understood that these are exemplary of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

### INDUSTRIAL APPLICABILITY

In accordance with the semiconductor device of the present invention, even when distortion, which has occurred in a specific transistor, varies after forming the device, stable transistor characteristics can be maintained. Therefore, the present invention contributes to providing a semiconductor device which has stable transistor characteristics, and can be manufactured at a low cost and by mass production.

What is claimed is:

1. A semiconductor device comprising:
a single-crystal semiconductor substrate; and
a stress applying device for applying a desired stress to specific one or more parts on or in the single-crystal semiconductor substrate.

2. A semiconductor device in accordance with claim 1, wherein the stress applying device includes:
a capacitance element, which is arranged in the vicinity of the specific one or more parts, and has a dielectric made of an electrostrictive material; and
a voltage applying device for applying a voltage in a direction parallel to a polarization vector of the dielectric.

3. The semiconductor device in accordance with claim 2, wherein the capacitance element is arranged on a side of the specific one or more parts and the direction of the polarization vector of the dielectric is parallel to the <110> or <100> direction with respect to the x-y-z coordinate system.

4. The semiconductor device in accordance with claim 2, wherein the capacitance element is arranged under the specific one or more parts, and the, direction of the polarization vector of the dielectric is parallel to the <110> or <100> direction with respect to the x-y-z coordinate system.

5. The semiconductor device in accordance with claim 1, wherein the specific one or more parts are one or more p-n junctions.

6. The semiconductor device in accordance with claim 5, wherein the one or more p-n junctions are each included in a MOS transistor.

7. The semiconductor device in accordance with claim 6, wherein each MOS transistor functions as a redundant cell for forming a DRAM.

8. The semiconductor device in accordance with claim 6, wherein each MOS transistor functions as a main cell for forming a DRAM.

9. A semiconductor devil in accordance with claim 1, wherein the desired stress is one of a compressive stress and a tensile stress.

10. A semiconductor device in accordance with claim 1, wherein the desired stress is applied in a predetermined direction.

11. A semiconductor device in accordance with claim 1, wherein the desired stress has an amount for applying a desired distortion to the specific one or more parts.
